(19) United States
(12) Patent Application Publication
(10) Pub. No.: US 2026/0361296 A1
(43) Pub. Date: Nov. 12, 2026

(54) SEMICONDUCTOR DEVICE

(71) Applicant: ROHM Co., Ltd., Kyoto (JP)

(72) Inventors: Tomofumi Tsuchida, Kyoto (JP); Makoto Yasusaka, Kyoto (JP)

(73) Assignee: ROHM Co., Ltd., Kyoto (JP)

(21) Appl. No.: 19/668,766

(22) Filed: May 5, 2026

(30) Foreign Application Priority Data
May 12, 2025 (JP) 2025-079595
Aug. 12, 2025 (JP) 2025-134456

(51) Int. Cl. H03K 5/24; H03K 3/3565; H03K 17/687

(52) U.S. Cl. CPC H03K 5/2472; H03K 3/3565; H03K 17/687

(57) ABSTRACT

Provided is a semiconductor device that includes an external terminal, a first resistor connected between the external terminal and an application terminal of a voltage signal, a comparison circuit that generates a comparison signal based on whether the voltage signal is higher than a threshold value, a first current path connected between the external terminal and a reference potential terminal, and a second current path connected between the application terminal of the voltage signal and the reference potential terminal and having a second impedance lower than a first impedance of the first current path. The second current path is conducted/cut off in response to the comparison signal.

### CROSS-REFERENCE TO RELATED APPLICATION

This application claims the priority benefits of Japanese application no. 2025-079595, filed on May 12, 2025 and Japanese application no. 2025-134456, filed on Aug. 12, 2025. The entirety of the above-mentioned patent application is hereby incorporated by reference herein and made a part of this specification.

### BACKGROUND

### Technical Field

The present disclosure relates to a semiconductor device.

### Description of Related Art

The external terminal of the semiconductor device may be pulled down or pulled up via a built-in or external resistor.

It is noted that Patent Document 1 may be cited as an example of conventional technology related to the above.

### Prior Art Documents

### Patent Documents

[Patent Document 1] Japanese Patent Application Laid-Open No. 2023-131967 (for example, resistor Rp in FIG. 3)

### BRIEF DESCRIPTION OF THE DRAWINGS

FIG. 1 is a diagram showing a first comparative example of a semiconductor device.

FIG. 2 is a diagram showing a relationship between an input voltage and an input current in a first comparative example.

FIG. 3 is a diagram showing a second comparative example of the semiconductor device.

FIG. 4 is a diagram showing a first embodiment of the semiconductor device.

FIG. 5 is a diagram showing a relationship between an input voltage and an input current in the first embodiment.

FIG. 6 is a diagram showing a second embodiment of the semiconductor device.

FIG. 7 is a diagram showing a third embodiment of the semiconductor device.

FIG. 8 is a diagram showing a fourth embodiment of the semiconductor device.

FIG. 9 is a diagram showing a fifth embodiment of the semiconductor device.

FIG. 10 is a diagram showing a sixth embodiment of the semiconductor device.

FIG. 11 is a diagram showing a seventh embodiment of the semiconductor device.

FIG. 12 is a diagram showing an eighth embodiment of the semiconductor device.

FIG. 13 is a diagram showing a ninth embodiment of the semiconductor device.

FIG. 14 is a diagram showing a vertical structure of a transistor.

FIG. 15 is a diagram showing Id-Vg characteristics of a transistor.

FIG. 16 is a diagram showing a tenth embodiment of the semiconductor device.

### DETAILED DESCRIPTION

### Semiconductor Device First Comparative Example

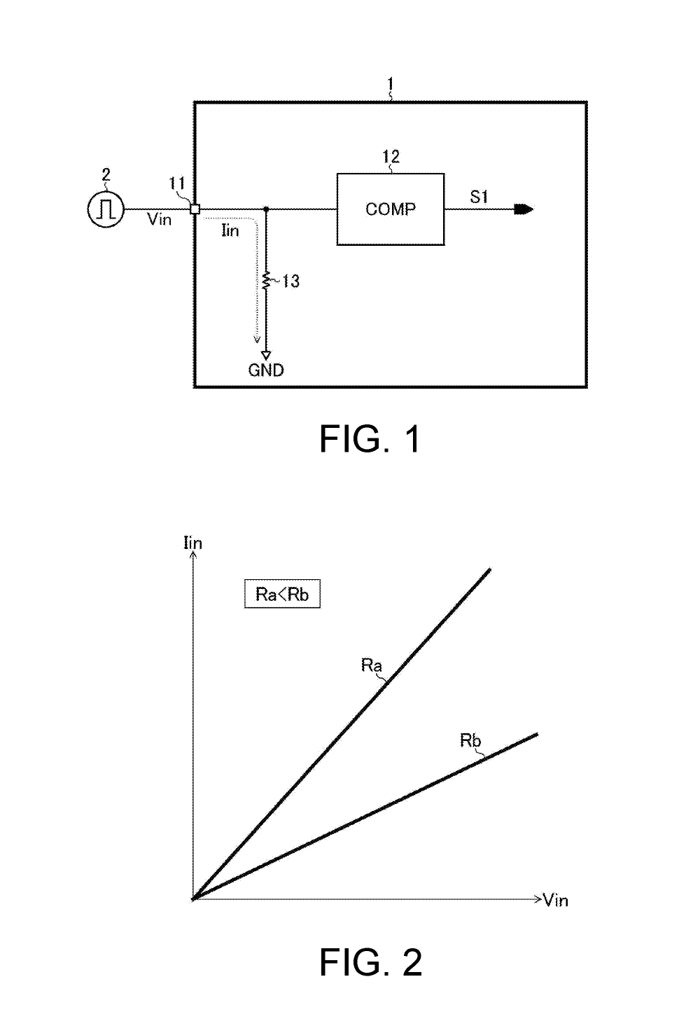

FIG. 1 is a diagram showing a first comparative example of a semiconductor device 1. The first comparative example may be understood as a general circuit configuration that is contrasted with various embodiments described later. The semiconductor device 1 of the first comparative example includes an external terminal 11, a comparison circuit 12, and a resistor 13.

The external terminal 11 may be connected to a signal source 2 provided outside the semiconductor device 1. The signal source 2 may be a microcomputer or the like. The signal source 2 applies an input voltage Vin to the external terminal 11. The input voltage Vin may be a logic signal that may take two values of a high level and a low level. The input voltage Vin may be, for example, an external enable signal for switching operation/non-operation of the semiconductor device 1. The semiconductor device 1 may be, for example, in an operating state when the input voltage Vin is Vina high level. On the other hand, the semiconductor device 1 may be, for example, in a non-operating state when the input voltage Vin is Vina low level.

The comparison circuit 12 generates a comparison signal S1 based on whether the input voltage Vin is higher than a threshold value. The comparison signal S1 may be, for example, an internal enable signal for switching operation/non-operation of an internal circuit not shown. That is, the comparison circuit 12 may be understood as a standby circuit that detects whether the input voltage Vin is applied and switches operation/non-operation of the internal circuit.

The resistor 13 is connected between the external terminal 11 and the ground terminal. That is, the external terminal 11 is pulled down to the ground terminal via the resistor 13. Thus, disturbances such as noise superimposed on the external terminal 11 are escaped to the ground terminal via the resistor 13. As a result, the internal circuit becomes less susceptible to the influence of disturbances, so malfunction of the semiconductor device 1 may be suppressed. It is noted that an input current Iin (=Vin/R, where R is the resistance value of the resistor 13) according to the input voltage Vin flows through the resistor 13.

FIG. 2 is a diagram showing the relationship between the input voltage Vin and the input current Iin in the first comparative example. Solid lines Ra and Rb may be understood as Vin-Iin characteristics when the resistance value of the resistor 13 is Ra and Rb (where Ra<Rb), respectively.

As shown in this figure, the smaller the resistance value of the resistor 13, the more the input current Iin increases. Thus, the noise immunity of the semiconductor device 1 is improved. Further, the resistor 13 may be formed by connecting a plurality of unit resistor elements in series. In this case, the smaller the resistance value of the resistor 13, the fewer the number of series stages of the unit resistor elements. Thus, the area of the resistor 13 may be small. However, since the input current Iin increases as the resistance value of the resistor 13 becomes smaller, the power consumption inside the semiconductor device 1, and consequently, the heat generation of the semiconductor device 1 becomes larger.

It is noted that if the resistance value of the resistor 13 is increased, the input current Iin decreases. However, the noise immunity of the semiconductor device 1 may deteriorate. Further, the larger the resistance value of the resistor 13, the more the number of series stages of unit resistor elements increases. Thus, the area of the resistor 13 becomes large.

### Semiconductor Device Second Comparative Example

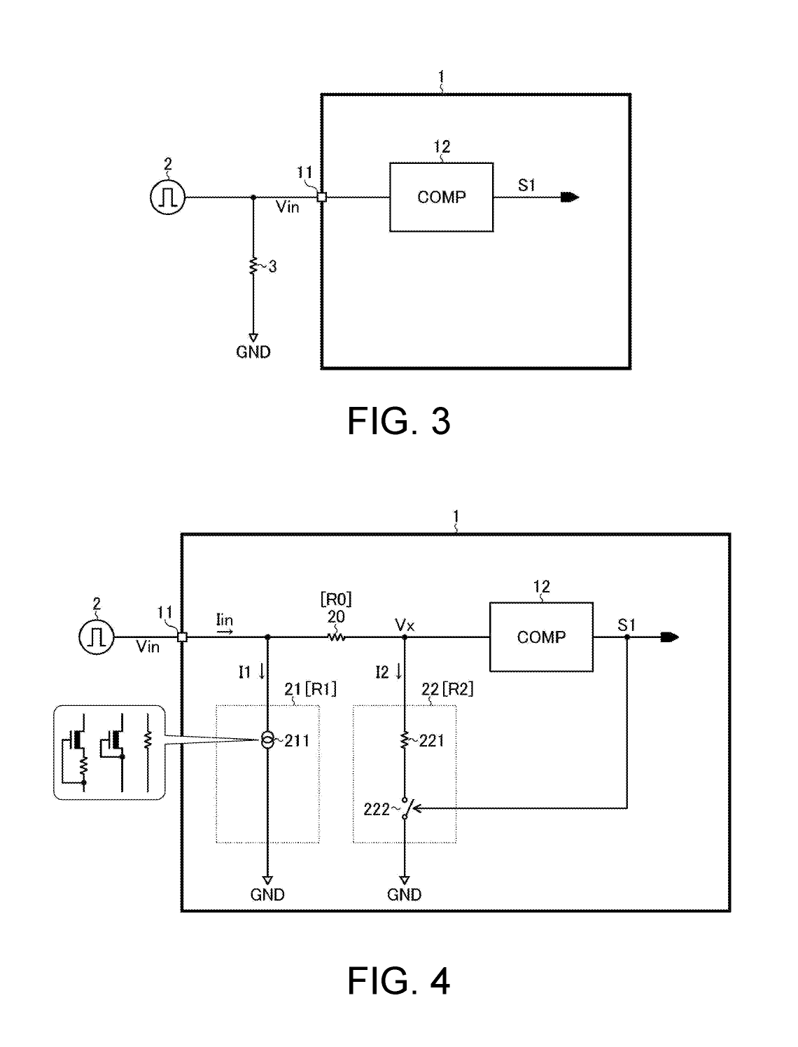

FIG. 3 is a diagram showing a second comparative example of the semiconductor device. The semiconductor device 1 of the second comparative example is based on the first comparative example (FIG. 1), but the resistor 13 is replaced with a discrete resistor 3. The resistor 3 is externally attached between the external terminal 11 and the ground terminal. With this configuration, current does not flow into the external terminal 11. However, since the external resistor 3 is required, the number of components increases. It is noted that if the resistor 3 is omitted to reduce the number of components, the noise immunity of the semiconductor device 1 may deteriorate.

### Semiconductor Device First Embodiment

FIG. 4 is a diagram showing a first embodiment of the semiconductor device 1. The semiconductor device 1 of the present embodiment is based on the aforementioned first comparative example (FIG. 1) and includes a resistor 20, a first current path 21, and a second current path 22 in place of the aforementioned resistor 13.

The resistor 20 corresponds to a first resistor connected between the external terminal 11 and an application terminal of a voltage signal Vx. The resistor 20 has a resistance value R0. The resistance value R0 may be, for example, several tens of kΩ. In the resistor 20, a current I2 may flow in a direction from the external terminal 11 to a ground terminal via the resistor 20 and the second current path 22. At this time, the voltage signal Vx becomes a voltage value obtained by subtracting a voltage across two terminals of the resistor 20 from the input voltage Vin (=Vin−I2×R0).

The first current path 21 is connected between the external terminal 11 and the ground terminal. The ground terminal may be understood as an example of a reference potential terminal to which a ground voltage GND is applied. A current I1 may flow through the first current path 21 in a direction from the external terminal 11 to the ground terminal via the first current path 21. The first current path 21 has a first impedance R1. The first impedance R1 may be, for example, several tens of MΩ.

According to this figure, the first current path 21 may include a current source 211. The current source 211 is connected between the external terminal 11 and the ground terminal and generates a current I1 of a constant value (substantially zero). However, the configuration of the first current path 21 is not limited thereto. For example, the first current path 21 may include at least one of a resistor and a depletion type transistor in which a gate and a source are short-circuited directly or through a resistor, instead of the current source 211 or together with the current source 211, as shown in the callout frame.

The second current path 22 is connected between an application terminal of the voltage signal Vx and a ground terminal. In the second current path 22, the current I2 may flow in a direction from the external terminal 11 through the resistor 20 and the second current path 22 to the ground terminal. The second current path 22 has a second impedance R2 that is lower than the first impedance R1. The second impedance R2 may be, for example, several tens of kΩ. The second current path 22 may be conducted/cut off according to the comparison signal S1.

According to this figure, the second current path 22 may include a resistor 221 and a switch 222. The resistor 221 corresponds to a second resistor whose first terminal is connected to an application terminal of the voltage signal Vx. The switch 222 is connected between a second terminal of the resistor 221 and a ground terminal. The switch 222 is turned on/off in response to the comparison signal S1. For example, the switch 222 may be in an on state when the comparison signal S1 is at a high level. Further, for example, the switch 222 may be in an off state when the comparison signal S1 is at a low level.

The comparison circuit 12 generates the comparison signal S1 based on whether the voltage signal Vx is higher than a threshold value. The comparison signal S1 may be a logic signal that may take two values of a high level and a low level. For example, the comparison signal S1 may become a low level when the voltage signal Vx is higher than the threshold value. On the other hand, the comparison signal S1 may become a high level when the voltage signal Vx is lower than the threshold value. The comparison signal S1 may be an internal enable signal for switching operation/non-operation of an internal circuit not shown, as described above. The internal circuit may be, for example, in an operating state when the comparison signal S1 is at a low level. On the other hand, the internal circuit may be, for example, in a non-operating state when the comparison signal S1 is at a high level.

When the input voltage Vin is at a high level, the voltage signal Vx becomes higher than the threshold value of the comparison circuit 12. At this time, the comparison signal S1 becomes a low level. Thus, the switch 222 turns to an off state, so the second current path 22 is cut off. As a result, the entire amount of the input current Iin flowing into the external terminal 11 flows into the first current path 21 as the current I1.

The first impedance R1 of the first current path 21 is higher than the second impedance R2 of the second current path 22. Thus, the input current Iin is limited compared to when the second current path 22 is conducted. As a result, the power consumption inside the semiconductor device 1, and consequently, the heat generation of the semiconductor device 1 is suppressed. In particular, with a configuration that uses the current source 211 to limit the current I1 to substantially zero, the first current path 21 may be designed with a smaller area than a configuration using high resistance.

On the other hand, when the input voltage Vin is at a low level, the voltage signal Vx becomes lower than the threshold value of the comparison circuit 12. At this time, the comparison signal S1 becomes a high level. Thus, since the switch 222 turns on, the second current path 22 is conducted.

The second impedance R2 of the second current path 22 is sufficiently lower than the first impedance R1 of the first current path 21. Thus, the input current Iin flowing into the external terminal 11 flows almost entirely as the current I2 to the second current path 22. In this way, when the input voltage Vin is at a low level, the impedance as viewed from the external terminal 11 is reduced. As a result, the internal circuit becomes less susceptible to the influence of disturbances, so the noise immunity of the semiconductor device 1 may be improved.

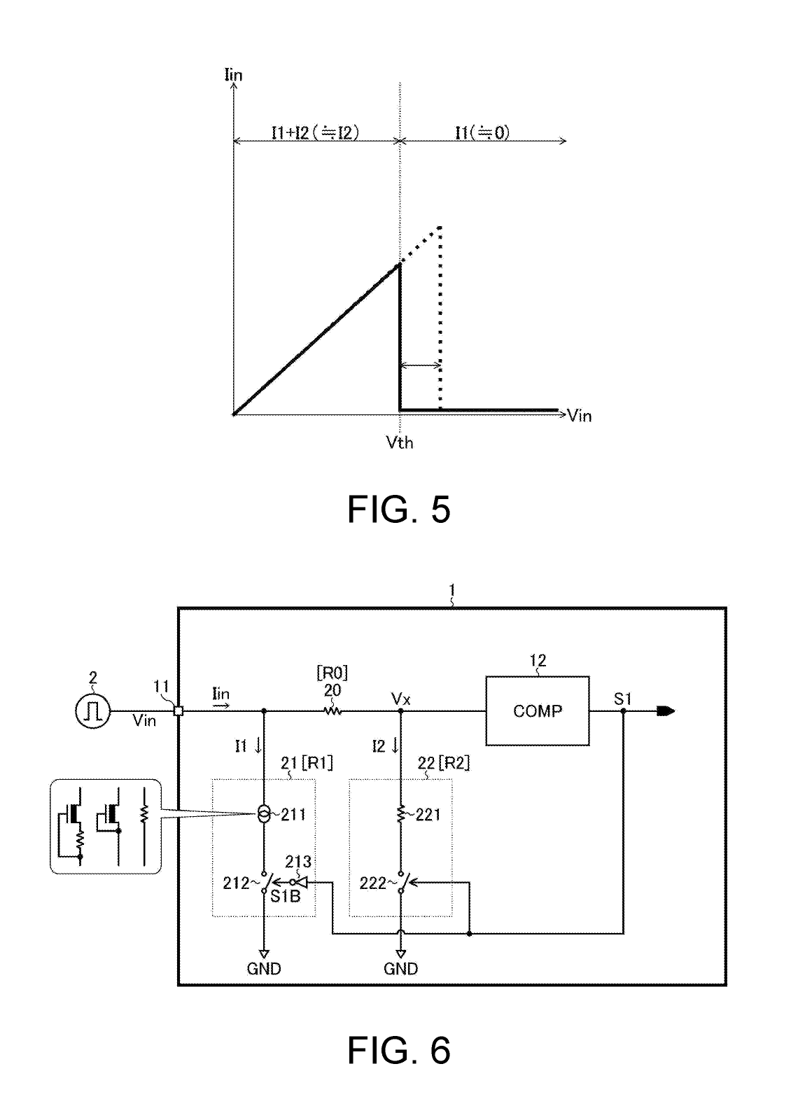

FIG. 5 is a diagram showing the relationship between the input voltage Vin and the input current Iin in the first embodiment. As shown in this figure, when the input voltage Vin is higher than a threshold voltage Vth, that is, when the voltage signal Vx is higher than the threshold value of the comparison circuit 12, Iin=I1(≒0) may be obtained. On the other hand, when the input voltage Vin is lower than threshold voltage Vth, that is, when the voltage signal Vx is lower than the threshold value of the comparison circuit 12, Iin=I1+I2(≒I2) may be obtained. The threshold voltage Vth may be adjusted according to the resistance value R0 of the resistor 20.

### Semiconductor Device Second Embodiment

FIG. 6 is a diagram showing a second embodiment of the semiconductor device 1. The semiconductor device 1 of this embodiment is based on the first embodiment (FIG. 4) described above, while the configuration and operation of the first current path 21 are changed. As described with reference to this figure, the first current path 21 includes, in addition to the current source 211 described above, a switch 212 and an inverter 213.

The switch 212 is connected between the current source 211 and the ground terminal. The switch 212 is turned on/off in response to an inverted comparison signal S1B. For example, the switch 212 may be in an on state when the inverted comparison signal S1B is at a high level. Further, for example, the switch 212 may be in an off state when the inverted comparison signal S1B is at a low level.

The inverter 213 inverts the logic level of the comparison signal S1 to generate an inverted comparison signal S1B. The inverted comparison signal S1B becomes a low level when the comparison signal S1 is at a high level. The inverted comparison signal S1B becomes a high level when the comparison signal S1 is at a low level.

Thus, the first current path 21 is complementarily conducted/cut off with the second current path 22 according to the comparison signal S1. That is, the first current path 21 is cut off when the second current path 22 is conducted. The first current path 21 is conducted when the second current path 22 is cut off. With this configuration, the power consumption of the first current path 21 may be reduced.

### Semiconductor Device Third Embodiment

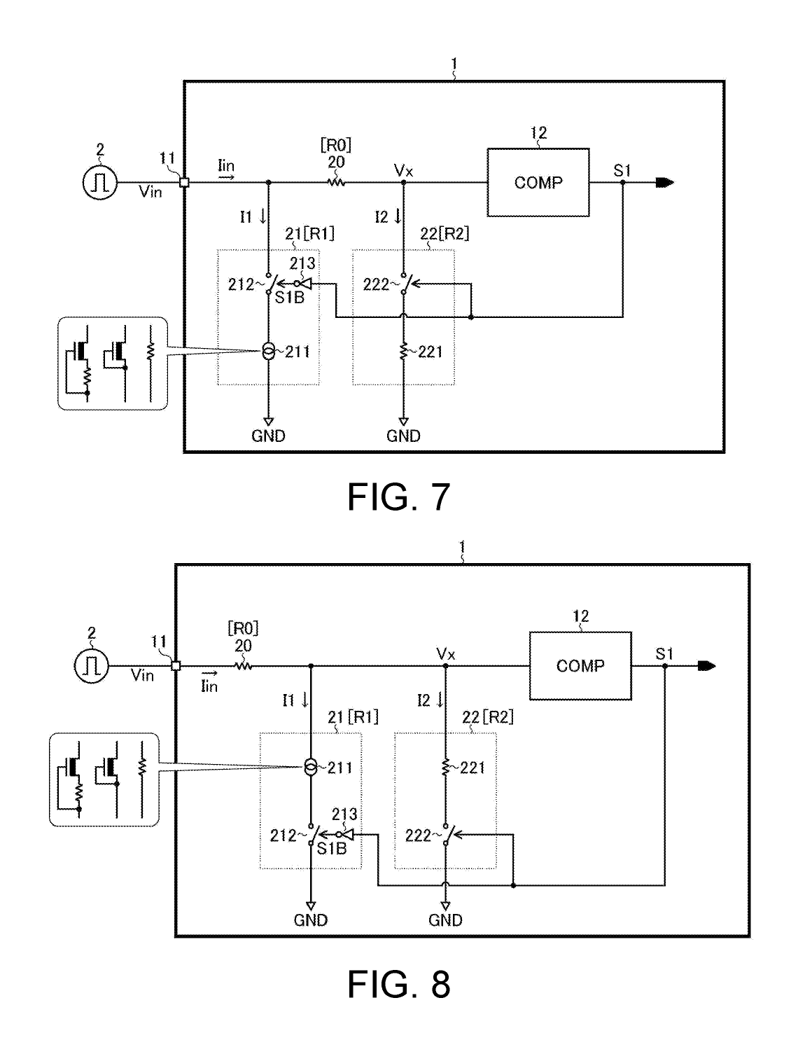

FIG. 7 is a diagram showing a third embodiment of the semiconductor device 1. The semiconductor device 1 of this embodiment is based on the second embodiment (FIG. 6) described above, while the relative positional relationship between the current source 211 and the switch 212, and the relative arrangement relationship between the resistor 221 and the switch 222 are respectively interchanged. In this way, the circuit configurations of the first current path 21 and the second current path 22 respectively may be arbitrarily changed within a range that may exhibit the aforementioned functions.

### Semiconductor Device Fourth Embodiment

FIG. 8 is a diagram showing a fourth embodiment of the semiconductor device 1. The semiconductor device 1 of this embodiment is based on the second embodiment (FIG. 6) described above, but the position where the first current path 21 is provided has been changed. Specifically referring to this figure, the first current path 21 may be connected between the application terminal of the voltage signal Vx and the ground terminal. In this way, the position where the first current path 21 is provided may be arbitrarily changed within a range that may exhibit the aforementioned function.

### Semiconductor Device Fifth Embodiment

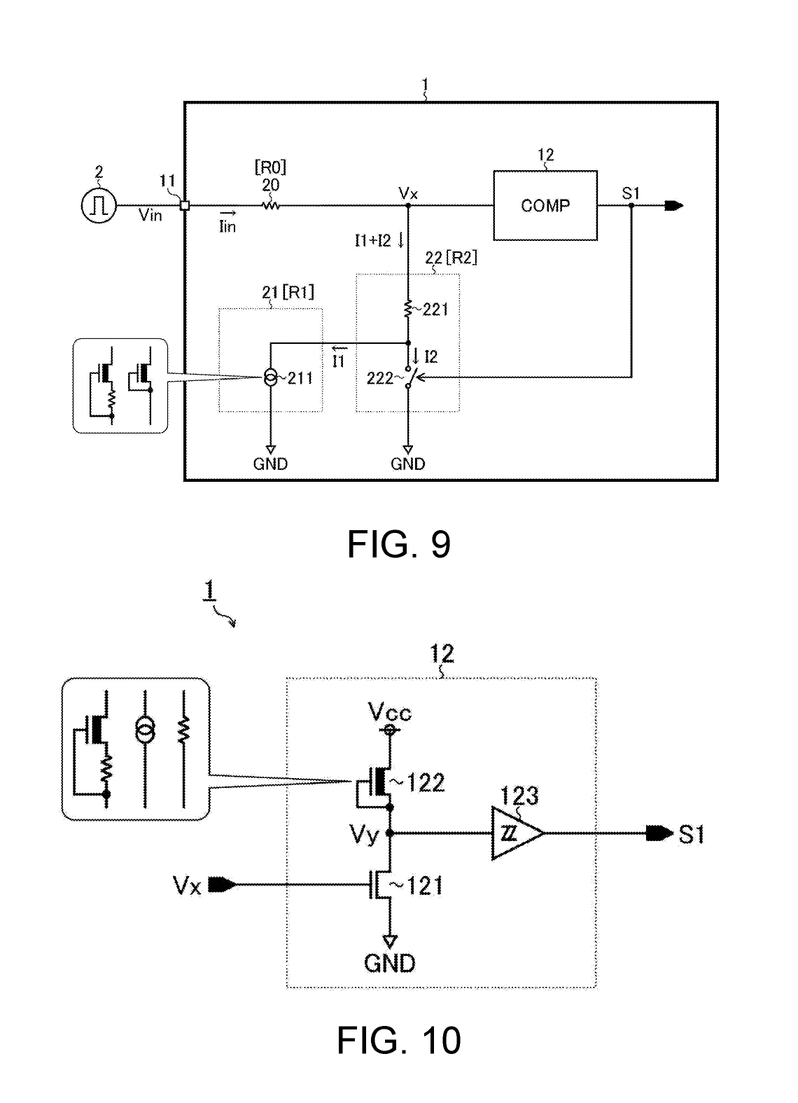

FIG. 9 is a diagram showing a fifth embodiment of the semiconductor device 1. The semiconductor device 1 of this embodiment is based on the first embodiment (FIG. 4) described above, but the position where the first current path 21 is provided is changed. Specifically referring to this figure, the first current path 21 is connected between the second terminal of the resistor 221 and the ground terminal. It is noted that the first current path 21 may include at least one of depletion type transistors in which a gate and a source are short-circuited directly or through a resistor, instead of the current source 211 or together with the current source 211, as shown in the callout frame.

### Semiconductor Device Sixth Embodiment

FIG. 10 is a diagram showing a sixth embodiment of the semiconductor device 1. The semiconductor device 1 of the sixth embodiment includes, as components of the comparison circuit 12, transistors 121 and 122, and a Schmitt trigger 123. The transistor 121 may be, for example, an enhancement type NMOSFET [N-channel type metal oxide semiconductor field effect transistor]. The transistor 122 may be, for example, a depletion type NMOSFET.

A gate of the transistor 121 is connected to an application terminal of the voltage signal Vx. A source of the transistor 121 is connected to a ground terminal. A drain of the transistor 121 is connected to an application terminal of a voltage signal Vy. The transistor 121 receives the voltage signal Vx at the gate and outputs the voltage signal Vy from the drain. The transistor 121 becomes an on state when a gate-source voltage (=Vx−GND) is higher than an on-threshold value of the transistor 121. At this time, the voltage signal Vy becomes a low level. On the other hand, the transistor 121 becomes an off state when the gate-source voltage (=Vx−GND) is lower than the on-threshold value of the transistor 121. At this time, the voltage signal Vy becomes a high level.

The drain of the transistor 122 is connected to a power supply terminal. The gate and the source of the transistor 122 are both connected to an application terminal of the voltage signal Vy. The transistor 122 connected in this manner may be understood as a drive current source that supplies a drive current to the transistor 121. As shown in the callout frame, the comparison circuit 12 may include at least one of a resistor, a current source, and a depletion type transistor in which a gate and a source are short-circuited through a resistor, instead of the transistor 122 or together with the transistor 122.

The Schmitt trigger 123 receives the drain voltage of the transistor 121, that is, the voltage signal Vy, and outputs a comparison signal S1. The comparison signal S1 becomes a high level when, for example, the voltage signal Vy is higher than a logic switching threshold value of the Schmitt trigger 123. On the other hand, the comparison signal S1 becomes a low level when, for example, the voltage signal Vy is lower than the logic switching threshold value of the Schmitt trigger 123. Hysteresis may be provided to the logic switching threshold value of the Schmitt trigger 123. The Schmitt trigger 123 may directly receive the voltage signal Vx. In that case, the transistors 121 and 122 may be omitted. It is noted that when the transistors 121 and 122 are omitted, the logic levels of signals input to and output from the Schmitt trigger 123 are inverted. Thus, an inverter may be added to the subsequent stage of the Schmitt trigger 123.

It is noted that the comparison circuit 12 of the present embodiment may be applied to any of the aforementioned first embodiment (FIG. 4), second embodiment (FIG. 6), third embodiment (FIG. 7), fourth embodiment (FIG. 8), and fifth embodiment (FIG. 9).

### Semiconductor Device Seventh Embodiment

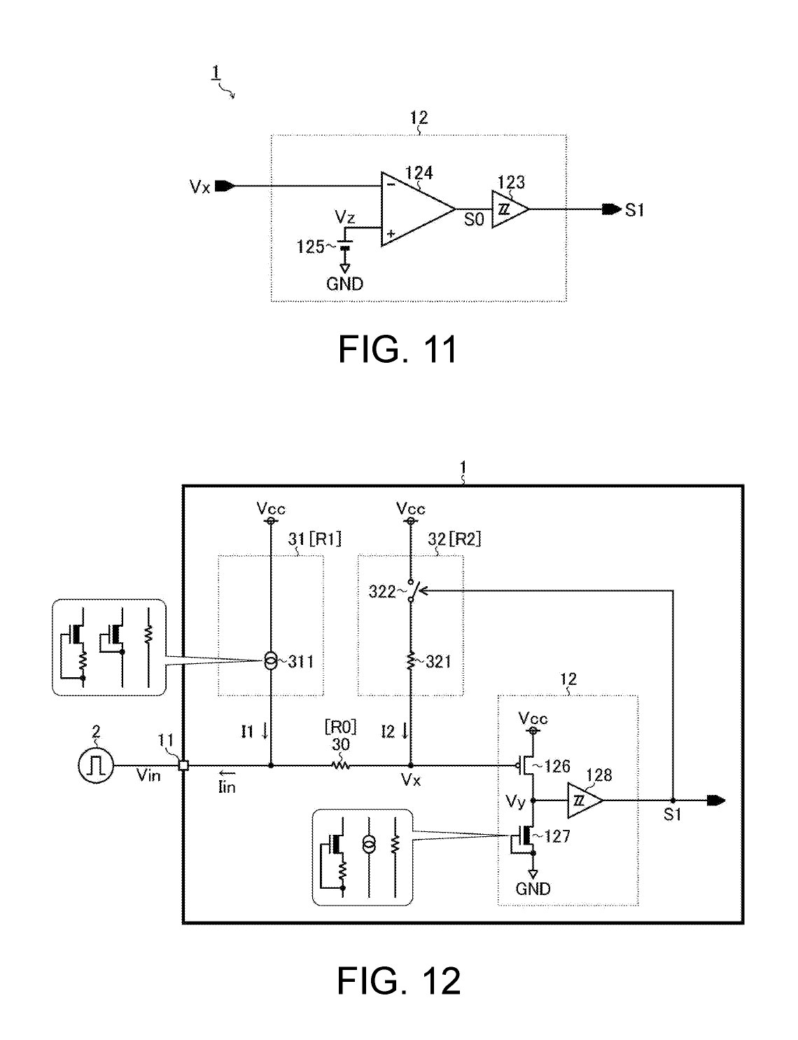

FIG. 11 is a diagram showing a seventh embodiment of the semiconductor device 1. The semiconductor device 1 of the seventh embodiment is based on the aforementioned sixth embodiment (FIG. 10) and includes a comparator 124 and a voltage source 125 instead of the transistors 121 and 122. The comparator 124 generates an output signal S0 by comparing a voltage signal Vx applied to an inverting input terminal (−) and a threshold voltage Vz applied to a non-inverting input terminal (+). The output signal S0 becomes a low level when the voltage signal Vx is higher than the threshold voltage Vz. On the other hand, the output signal S0 becomes a high level when the voltage signal Vx is lower than the threshold voltage Vz. The voltage source 125 generates the threshold voltage Vz. In this way, the comparison circuit 12 may be formed by a voltage comparison type comparator 124. However, the voltage source 125 is required.

### Semiconductor Device Eighth Embodiment

FIG. 12 is a diagram showing an eighth embodiment of the semiconductor device 1. The semiconductor device 1 of the eighth embodiment is based on the first comparative example (FIG. 1) described above, and includes a resistor 30, a first current path 31, and a second current path 32 in place of the resistor 13 described above.

The resistor 30 corresponds to a first resistor connected between the external terminal 11 and an application terminal of a voltage signal Vx. The resistor 30 has a resistance value R0. The resistance value R0 may be, for example, several tens of kΩ. In the resistor 30, a current I2 may flow in a direction from a power supply terminal to the external terminal 11 via the second current path 32 and the resistor 30. At this time, the voltage signal Vx becomes a voltage value (=Vin+I2×R0) obtained by adding the voltage across two terminals of the resistor 30 to the input voltage Vin.

The first current path 31 is connected between the external terminal 11 and the power supply terminal. The power supply terminal may be understood as an example of a reference potential terminal to which a power supply voltage Vcc is applied. A current I1 may flow through the first current path 31 in a direction from the power supply terminal to the external terminal 11 via the first current path 31. The first current path 31 has a first impedance R1. The first impedance R1 may be, for example, several tens of MΩ.

According to this figure, the first current path 31 may include a current source 311. The current source 311 is connected between the external terminal 11 and the power supply terminal and generates a current I1 of a constant value (substantially zero). However, the configuration of the first current path 31 is not limited thereto. For example, the first current path 31 may include at least one of a resistor and a depletion type transistor in which a gate and a source are short-circuited directly or through a resistor, instead of the current source 311 or together with the current source 311, as shown in the callout frame.

The second current path 32 is connected between an application terminal of the voltage signal Vx and the power supply terminal. In the second current path 32, the current I2 may flow in a direction from the power supply terminal to the external terminal 11 via the second current path 32 and resistor 30. The second current path 32 has a second impedance R2 that is lower than the first impedance R1. The second impedance R2 may be, for example, several tens of kΩ. The second current path 32 may be conducted/cut off according to the comparison signal S1.

According to this figure, the second current path 32 may include a resistor 321 and a switch 322. The resistor 321 corresponds to a second resistor whose first terminal is connected to an application terminal of the voltage signal Vx. The switch 322 is connected between a second terminal of the resistor 321 and the power supply terminal. The switch 322 is turned on/off in response to the comparison signal S1. For example, the switch 322 may be in an on state when the comparison signal S1 is at a high level. Further, for example, the switch 322 may be in an off state when the comparison signal S1 is at a low level.

The comparison circuit 12 generates the comparison signal S1 based on whether the voltage signal Vx is higher than a threshold value. The comparison signal S1 may be a logic signal that may take two values of a high level and a low level. For example, the comparison signal S1 may become a low level when the voltage signal Vx is higher than the threshold value. On the other hand, the comparison signal S1 may become a high level when the voltage signal Vx is lower than the threshold value. The comparison signal S1 may be an internal enable signal for switching operation/non-operation of an internal circuit not shown, as described above. The internal circuit may be, for example, in an operating state when the comparison signal S1 is at a low level. On the other hand, the internal circuit may be, for example, in a non-operating state when the comparison signal S1 is at a high level.

According to this figure, the comparison circuit 12 includes transistors 126 and 127, and a Schmitt trigger 128. The transistor 126 may be, for example, an enhancement type PMOSFET [P-channel type MOSFET]. The transistor 127 may be, for example, a depletion type NMOSFET.

A gate of the transistor 126 is connected to an application terminal of the voltage signal Vx. A source of transistor 126 is connected to the power supply terminal. A drain of the transistor 126 is connected to an application terminal of a voltage signal Vy. The transistor 126 receives the voltage signal Vx at the gate and outputs the voltage signal Vy from the drain. The transistor 126 becomes an on state when a gate-source voltage (=Vcc−Vx) is higher than an on-threshold value of the transistor 126. At this time, the voltage signal Vy becomes a low level. On the other hand, the transistor 126 becomes an off state when the gate-source voltage (=Vcc−Vx) is lower than the on-threshold value of the transistor 126. At this time, the voltage signal Vy becomes a high level.

A drain of the transistor 127 is connected to an application terminal of a voltage signal Vy. A gate and a source of the transistor 127 are both connected to a ground terminal. The transistor 127 connected in this manner may be understood as a drive current source that supplies a drive current to the transistor 126. As shown in the callout frame, the comparison circuit 12 may include at least one of a resistor, a current source, and a depletion type transistor in which a gate and a source are short-circuited through a resistor, instead of the transistor 127 or together with the transistor 127.

The Schmitt trigger 128 receives the drain voltage of the transistor 126, that is, the voltage signal Vy, and outputs a comparison signal S1. The comparison signal S1 becomes a high level when, for example, the voltage signal Vy is higher than a logic switching threshold value of the Schmitt trigger 128. On the other hand, the comparison signal S1 becomes a low level when, for example, the voltage signal Vy is lower than the logic switching threshold value of the Schmitt trigger 128. Hysteresis may be provided to the logic switching threshold value of the Schmitt trigger 128. The Schmitt trigger 128 may directly receive the voltage signal Vx. In that case, the transistors 126 and 127 may be omitted.

When the input voltage Vin is at a high level, the comparison signal S1 becomes a low level. Thus, the switch 322 turns to an off state, so the second current path 32 is cut off. As a result, the entire amount of the input current Iin flowing out to the external terminal 11 flows into the first current path 31 as the current I1.

The first impedance R1 of the first current path 31 is higher than the second impedance R2 of the second current path 32. Thus, the input current Iin is limited compared to when the second current path 32 is conducted. As a result, the power consumption inside the semiconductor device 1, and consequently, the heat generation of the semiconductor device 1 is suppressed. In particular, with a configuration that uses the current source 311 to limit the current I1 to substantially zero, the first current path 31 may be designed with a smaller area than a configuration using high resistance.

On the other hand, when the input voltage Vin is at a low level, the comparison signal S1 becomes a high level.

Thus, since the switch 322 turns on, the second current path 32 is conducted.

The second impedance R2 of the second current path 32 is sufficiently lower than the first impedance R1 of the first current path 31. Thus, the input current Iin flowing out to the external terminal 11 flows almost entirely as the current I2 to the second current path 32. In this way, when the input voltage Vin is at a low level, the impedance as viewed from the external terminal 11 is reduced. As a result, the internal circuit becomes less susceptible to the influence of disturbances, so the noise immunity of the semiconductor device 1 may be improved.

By the way, in the present embodiment, the constituent elements of the comparison circuit 12 are explicitly shown. However, this configuration is merely exemplary, and it goes without saying that various modifications are possible. For example, the comparison circuit 12 may have a circuit configuration similar to the aforementioned FIG. 10. Further, for example, the comparison circuit 12 may include a normal comparator as a constituent element, similar to the aforementioned FIG. 11. That is, the comparison circuit 12 may be understood as one functional block, similar to the aforementioned FIGS. 1, 3, 4, and 6-9.

It is noted that in FIGS. 10 and 12, the meaning of the threshold value in the comparison circuit 12 is different. In the comparison circuit 12 of FIG. 10, a determination is made as to whether the voltage generated with respect to GND exceeds the threshold value. In contrast, in the comparison circuit 12 of FIG. 12, a determination is made as to whether the voltage generated with respect to Vcc exceeds the threshold value.

### Considerations Regarding Comparison Circuit

In the comparison circuit 12 of the sixth embodiment (FIG. 10), a configuration combining an enhancement type transistor 121 and a depletion type transistor 122 was adopted. With this configuration, the threshold voltage of the comparison circuit 12 becomes less susceptible to the influence of temperature changes. However, the transistors 121 and 122 each have different device structures formed on the semiconductor substrate, so-called lower layer structures. Thus, the threshold voltage of the comparison circuit 12 is susceptible to the influence of element variations in the transistors 121 and 122. To address this issue, it is necessary to repair the threshold voltage of the comparison circuit 12 during testing of the semiconductor device 1. However, this approach may lead to an increase in the area of the semiconductor device 1 and an extension of the required test time. In view of the above considerations, a comparison circuit 12 that is less susceptible to the influence of element variations is proposed below.

### Semiconductor Device Ninth Embodiment

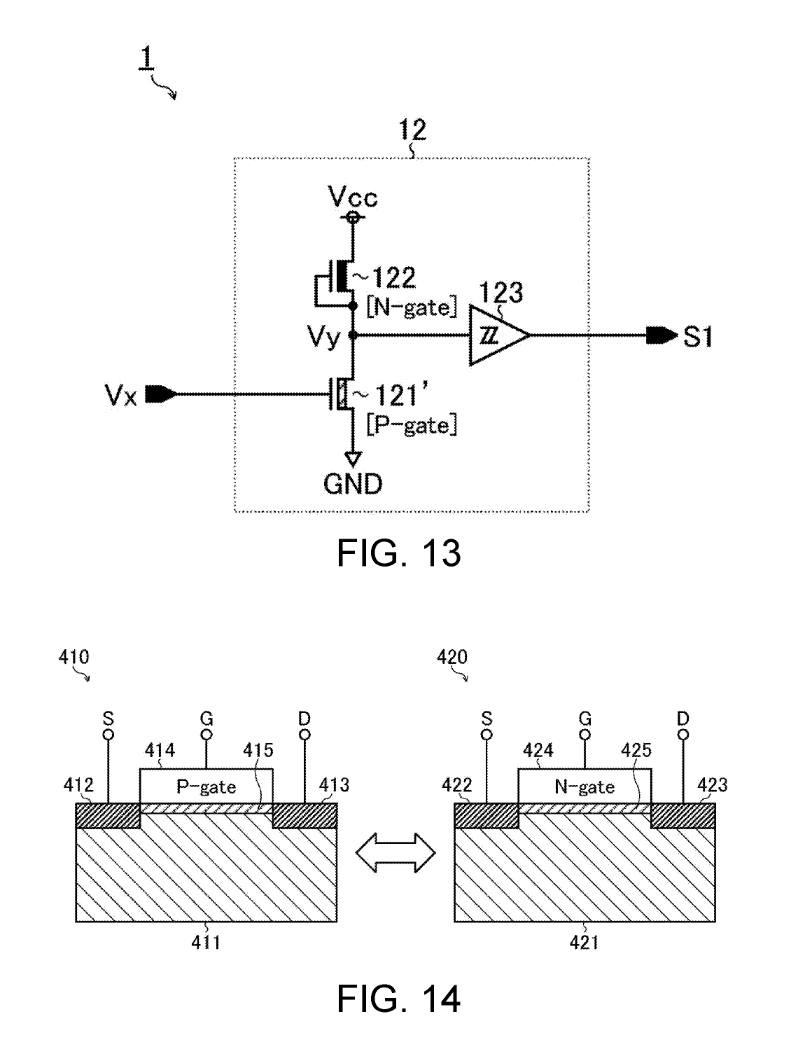

FIG. 13 is a diagram showing a ninth embodiment of the semiconductor device 1. The semiconductor device 1 of the ninth embodiment is based on the aforementioned sixth embodiment (FIG. 10), while changes are made to the configuration of the comparison circuit 12. Speaking with reference to this figure, the comparison circuit 12 includes a transistor 121’ in place of the enhancement type transistor 121.

The transistor 121’ may be a P gate depletion type NMOSFET in which a P-type impurity is injected into the gate. The transistor 121’ may be understood as a first transistor that receives the voltage signal Vx at the gate, similar to the transistor 121.

The transistor 122 may be an N gate depletion type NMOSFET in which an N-type impurity is injected into the gate. The transistor 122 may be understood as a second transistor that supplies a drive current to the transistor 121’.

FIG. 14 is a diagram showing the vertical structure of transistors 410 and 420. The transistor 410 is a P gate depletion type NMOSFET. The transistor 410 corresponds to the transistor 121’. The transistor 420 is an N gate depletion type NMOSFET. The transistor 420 corresponds to the transistor 122.

According to this figure, the transistor 410 includes a P-type semiconductor region 411, N-type semiconductor regions 412 and 413, and a P-type gate 414. The P-type semiconductor region 411 may be a P-type well. The N-type semiconductor regions 412 and 413 may each be formed in the P-type semiconductor region 411. The N-type semiconductor region 412 may be connected to a source electrode S of the transistor 410. The N-type semiconductor region 413 may be connected to a drain electrode D of the transistor 410. The P-type gate 414 may be formed between the N-type semiconductor region 412 and the N-type semiconductor region 413. The P-type gate 414 may be connected to a gate electrode G of the transistor 410. The P-type impurity may be implanted into the P-type gate 414. A channel region 415 may be formed in a region directly below the P-type gate 414.

On the other hand, the transistor 420 includes a P-type semiconductor region 421, N-type semiconductor regions 422 and 423, and an N-type gate 424. The P-type semiconductor region 421 may be a P-type well. The N-type semiconductor regions 422 and 423 may each be formed in the P-type semiconductor region 421. The N-type semiconductor region 422 may be connected to a source electrode S of the transistor 420. The N-type semiconductor region 423 may be connected to a drain electrode D of the transistor 420. The N-type gate 424 may be formed between the N-type semiconductor region 422 and the N-type semiconductor region 423. The N-type gate 424 may be connected to a gate electrode G of the transistor 420. The N-type impurity may be implanted into the N-type gate 424. A channel region 425 may be formed in a region directly below the N-type gate 424.

In this way, the transistors 410 and 420 have different impurities injected into the gates, while having a common device structure formed on the semiconductor substrate, so-called lower layer structure.

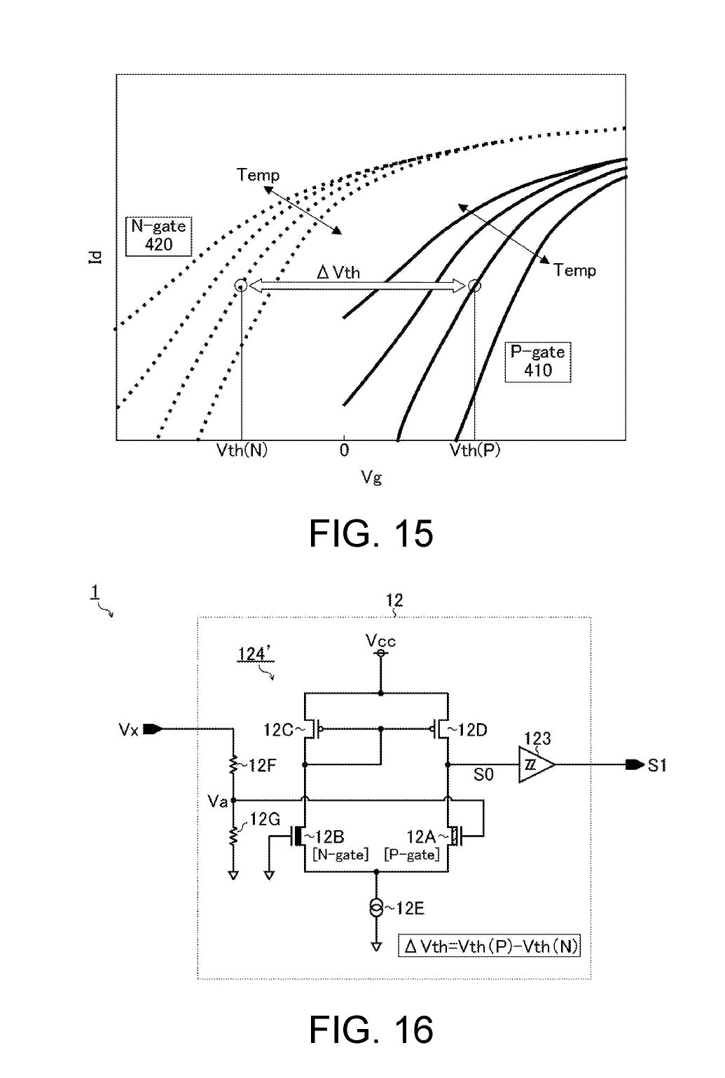

FIG. 15 is a diagram showing the Id-Vg characteristics of the transistors 410 and 420, respectively. The horizontal axis shows the gate voltage Vg of the transistors 410 and 420, respectively. The vertical axis shows the drain current Id of the transistors 410 and 420, respectively. The solid line shows the Id-Vg characteristics of the transistor 410. The broken line shows the Id-Vg characteristics of the transistor 420.

As shown in this figure, the transistor 410 may be element-designed to have a positive on-threshold voltage Vth(P). On the other hand, the transistor 420 may be element-designed to have a negative on-threshold voltage Vth(N). It is noted that the Id-Vg characteristics of the transistors 410 and 420, respectively, change with equivalent behavior with respect to temperature change. Thus, the differential voltage ΔVth between the on-threshold voltage Vth(P) of the transistor 410 and the on-threshold voltage Vth(N) of the transistor 420 may be substantially a constant value regardless of temperature change.

By the way, in the semiconductor device 1 of the present embodiment, the transistors 121’ and 122 forming the comparison circuit 12 have a common lower layer structure, similar to the transistors 410 and 420. Thus, compared to the aforementioned sixth embodiment (FIG. 10), the threshold voltage of the comparison circuit 12 is less susceptible to the influence of element variations. Accordingly, in the present embodiment, reduction in area of the semiconductor device 1 and shortening of test required time may be realized. Further, the threshold voltage of the comparison circuit 12 is less susceptible to the influence of temperature changes. In this respect, there is no difference from the sixth embodiment (FIG. 10).

It is noted that the comparison circuit 12 of the present embodiment may be applied to all semiconductor devices in which a standby circuit that switches on/off of internal circuits is introduced.

### Semiconductor Device Tenth Embodiment

FIG. 16 is a diagram showing a tenth embodiment of the semiconductor device 1. The semiconductor device 1 of the tenth embodiment is based on the aforementioned seventh embodiment (FIG. 11), while changes are made to the configuration of the comparison circuit 12. Speaking with reference to this figure, the comparison circuit 12 includes a comparator 124’ in place of the comparator 124 and the voltage source 125.

The comparator 124’ compares a divided voltage signal Va of the voltage signal Vx with the threshold voltage ΔVth. For example, the comparator 124’ includes transistors 12A and 12B, transistors 12C and 12D, a current source 12E, and resistors 12F and 12G.

The transistors 12A and 12B correspond to a pair of first transistor and second transistor forming a differential input stage of the comparator 124’. The transistor 12A may be a P gate depletion type NMOSFET in which a P-type impurity is injected into the gate. The transistor 12B may be an N gate depletion type NMOSFET in which an N-type impurity is injected into the gate. That is, the device structures of the transistors 12A and 12B respectively may be equivalent to the device structures of the aforementioned transistors 410 and 420, respectively (FIG. 14). Further, the Id-Vg characteristics of the transistors 12A and 12B, respectively, may be equivalent to the Id-Vg characteristics of the aforementioned transistors 410 and 420, respectively (FIG. 15). The transistors 12C and 12D may each be enhancement type PMOSFETs.

The sources of the transistors 12C and 12D are respectively connected to an application terminal of the power supply voltage Vcc. The gates of the transistors 12C and 12D are respectively connected to the drain of the transistor 12C. The drain of the transistor 12C is connected to a drain of the transistor 12B. The drains of the transistors 12A and 12D are respectively connected to an application terminal of the output signal S0. The sources of the transistors 12A and 12B are respectively connected to a first terminal of the current source 12E. A first terminal of the resistor 12F is connected to an application terminal of the voltage signal Vx. A second terminal of the resistor 12F, a first terminal of the resistor 12G, and a gate of the transistor 12A are connected to an application terminal of the divided voltage signal Va. A second terminal of the resistor 12G, a second terminal of the current source 12E, and a gate of the transistor 12B are connected to a ground terminal.

The comparator 124’ compares the divided voltage signal Va with the threshold voltage ΔVth to generate the output signal S0. The threshold voltage ΔVth becomes the differential voltage ΔVth between the on-threshold voltage Vth(P) of the transistor 12A and the on-threshold voltage Vth(N) of the transistor 12B. In this embodiment, the same operational effects as the aforementioned ninth embodiment (FIG. 13) may be obtained.

It is noted that, the comparator 124’ may be configured to compare the voltage signal Vx with the threshold voltage ΔVth. In that case, the resistors 12F and 12G may be omitted, and the gate of the transistor 12A may be connected to an application terminal of the voltage signal Vx.

### Combination of Multiple Embodiments

The various embodiments described so far may be implemented in any combination within a non-contradictory range. For example, in the eighth embodiment (FIG. 12), following the second embodiment (FIG. 6), a switch may be provided between the power supply terminal and the current source 311. Following the third embodiment (FIG. 7), the positions of the resistor 321 and the switch 322 may be interchanged. Following the fourth embodiment (FIG. 8), the first current path 31 may be connected between the power supply terminal and the application terminal of the voltage signal Vx. Following the fifth embodiment (FIG. 9), a current source may be connected in parallel to the switch 322. Further, the comparison circuit 12 of the ninth embodiment (FIG. 13) or the tenth embodiment (FIG. 16) may be applied to any of the first embodiment (FIG. 4), the second embodiment (FIG. 6), the third embodiment (FIG. 7), the fourth embodiment (FIG. 8), the fifth embodiment (FIG. 9), and the eighth embodiment (FIG. 12).

### Supplementary Note

According to the present disclosure, it becomes possible to reduce current flowing to the external terminal. Below, the above disclosure is additionally described.

### Supplementary Note 1

A semiconductor device (1), including an external terminal (11);
a first resistor (20, 30) configured to be connected between the external terminal (11) and an application terminal of a voltage signal (Vx);
a comparison circuit (12) configured to generate a comparison signal (S1) based on whether the voltage signal (Vx) is higher than a threshold value;
a first current path (21, 31) configured to be connected between the external terminal (11) and a reference potential terminal; and
a second current path (22, 32) connected between an application terminal of the voltage signal (Vx) and the reference potential terminal and configured to have a second impedance (R2) lower than a first impedance (R1) of the first current path (21, 31).
The second current path (22, 32) is configured to be conducted/cut off in response to the comparison signal (S1).

### Supplementary Note 2

In the semiconductor device (1) according to supplementary note 1, the first current path (21) includes at least one of a current source, a resistor, and a depletion type transistor in which a gate and a source are short-circuited directly or through a resistor.

### Supplementary Note 3

In the semiconductor device (1) according to supplementary note 1 or 2, the second current path (22, 32) includes:
a second resistor (221, 321) configured such that a first terminal is connected to an application terminal of the voltage signal (Vx); and
a switch (222, 322) connected between a second terminal of the second resistor (221, 321) and the reference potential terminal and configured to be turned on/off in response to the comparison signal (S1).

### Supplementary Note 4

In the semiconductor device (1) according to any one of supplementary notes 1 to 3, the first current path (21) is configured to be turned on/off complementarily with the second current path (22) in response to the comparison signal (S1).

### Supplementary Note 5

In the semiconductor device (1) according to any one of supplementary notes 1 to 4, the first current path (21) is configured to be connected between an application terminal of the voltage signal (Vx) and the reference potential terminal.

### Supplementary Note 6

In the semiconductor device (1) according to supplementary note 3, the first current path (21) is configured to be connected between a second terminal of the second resistor (221) and the reference potential terminal.

### Supplementary Note 7

In the semiconductor device (1) according to any one of supplementary notes 1 to 6, the comparison circuit (12) includes
a first transistor (121, 121’, 126) configured to receive the voltage signal (Vx) at a gate;
a drive current source (122, 127) configured to supply a drive current to the first transistor (121, 121’, 126); and
a Schmitt trigger (123) configured to receive a drain voltage (Vy) of the first transistor (121, 121’, 126) and output the comparison signal (S1).

### Supplementary Note 8

In the semiconductor device (1) according to supplementary note 7, the drive current source (122, 127) includes a depletion type second transistor (122, 127) configured such that a gate and a source are connected.

### Supplementary Note 9

In the semiconductor device (1) according to supplementary note 8, the first transistor (121) is an enhancement type.

### Supplementary Note 10

In the semiconductor device (1) according to supplementary note 8, the first transistor (121’) is a depletion type in which a P-type impurity is injected into a gate, and
the second transistor (122) is a depletion type in which an N-type impurity is injected into a gate.

### Supplementary Note 11

In the semiconductor device (1) according to any one of supplementary notes 1 to 6, the comparison circuit (12) includes
a comparator (124, 124’) configured to compare the voltage signal (Vx) or a divided voltage signal (Va) of the voltage signal with a threshold voltage (Vz, ΔVth); and
a Schmitt trigger (123) configured to receive an output signal (S0) of the comparator (124, 124’) and output the comparison signal (S1).

### Supplementary Note 12

In the semiconductor device (1) according to supplementary note 11, the comparator (124’) includes a pair of a first transistor (12A) and a second transistor (12B) configured to form a differential input stage,
the first transistor (12A) is a depletion type in which a P-type impurity is injected into a gate, and
the second transistor (12B) is a depletion type in which an N-type impurity is injected into a gate.

### Supplementary Note 13

In the semiconductor device (1) according to supplementary note 12, a gate of the first transistor (12A) is connected to an application terminal of the voltage signal (Vx) or the divided voltage signal (Va), and a gate of the second transistor (12B) is connected to the reference potential terminal.

### Supplementary Note 14

In the semiconductor device (1) according to any one of supplementary notes 1 to 13, the reference potential terminal is a ground terminal or a power supply terminal.

### Supplementary Note 15

In the semiconductor device (1) according to any one of supplementary notes 1 to 14, the comparison signal (S1) is an enable signal for switching operation/non-operation of an internal circuit.

### Others

It is noted that the various technical features disclosed in this specification may be modified in various ways within the scope of not departing from the gist of the technical creation, in addition to the above embodiments. That is, the above embodiments should be considered to be illustrative in all respects and not restrictive. Further, the technical scope of the present disclosure is defined by the claims, and it should be understood that all modifications belonging to the meaning and scope equivalent to the claims are included.

What is claimed is:

1. A semiconductor device, comprising:
an external terminal;
a first resistor configured to be connected between the external terminal and an application terminal of a voltage signal;
a comparison circuit configured to generate a comparison signal based on whether the voltage signal is higher than a threshold value;
a first current path configured to be connected between the external terminal and a reference potential terminal; and
a second current path connected between an application terminal of the voltage signal and the reference potential terminal and configured to have a second impedance lower than a first impedance of the first current path,
wherein the second current path is configured to be conducted/cut off in response to the comparison signal.

2. The semiconductor device according to claim 1, wherein the first current path comprises at least one of a current source, a resistor, and a depletion type transistor in which a gate and a source are short-circuited directly or through a resistor.

3. The semiconductor device according to claim 1, wherein the second current path comprises:
a second resistor configured such that a first terminal is connected to an application terminal of the voltage signal; and
a switch connected between a second terminal of the second resistor and the reference potential terminal and configured to be turned on/off in response to the comparison signal.

4. The semiconductor device according to claim 1, wherein the first current path is configured to be turned on/off complementarily with the second current path in response to the comparison signal.

5. The semiconductor device according to claim 1, wherein the first current path is configured to be connected between an application terminal of the voltage signal and the reference potential terminal.

6. The semiconductor device according to claim 3, wherein the first current path is configured to be connected between a second terminal of the second resistor and the reference potential terminal.

7. The semiconductor device according to claim 1, wherein the comparison circuit comprises:
a first transistor configured to receive the voltage signal at a gate;
a drive current source configured to supply a drive current to the first transistor; and
a Schmitt trigger configured to receive a drain voltage of the first transistor and output the comparison signal.

8. The semiconductor device according to claim 7, wherein the drive current source comprises a depletion type second transistor configured such that a gate and a source are connected.

9. The semiconductor device according to claim 8, wherein the first transistor is an enhancement type.

10. The semiconductor device according to claim 8, wherein the first transistor is a depletion type in which a P-type impurity is injected into a gate, and
the second transistor is a depletion type in which an N-type impurity is injected into a gate.

11. The semiconductor device according to claim 1, wherein the comparison circuit comprises:
a comparator configured to compare the voltage signal or a divided voltage signal of the voltage signal with a threshold voltage; and
a Schmitt trigger configured to receive an output signal of the comparator and output the comparison signal.

12. The semiconductor device according to claim 11, wherein the comparator comprises a pair of a first transistor and a second transistor configured to form a differential input stage,
the first transistor is a depletion type in which a P-type impurity is injected into a gate, and
the second transistor is a depletion type in which an N-type impurity is injected into a gate.

13. The semiconductor device according to claim 12, wherein a gate of the first transistor is connected to an application terminal of the voltage signal or the divided voltage signal, and a gate of the second transistor is connected to the reference potential terminal.

14. The semiconductor device according to claim 1, wherein the reference potential terminal is a ground terminal or a power supply terminal.

15. The semiconductor device according to claim 1, wherein the comparison signal is an enable signal for switching operation/non-operation of an internal circuit.
